(19) United States
(12) Patent Application Publication
(10) Pub. No.: US 2025/0113532 A1
(43) Pub. Date: Apr. 3, 2025

(54) TRANSISTOR DEVICE WITH AN EDGE TERMINATION STRUCTURE AND METHOD

(71) Applicant: Infineon Technologies Austria AG, Villach (AT)

(72) Inventors: Christian Fachmann, Villach (AT); Franz Hirler, Isen (DE); Winfried Kaindi, Unterhaching (DE); Hans Weber, Villach (AT); Armin Willmeroth, Friedberg (DE)

(21) Appl. No.: 18/897,040

(22) Filed: Sep. 26, 2024

(30) Foreign Application Priority Data
Sep. 29, 2023 (DE) 102023126745.0

(51) Int. Cl. H01L 29/78; H01L 21/265; H01L 29/06; H01L 29/40

(52) U.S. Cl. CPC H10D 30/665; H01L 21/26513; H01L 21/26586; H10D 30/668; H10D 62/111; H10D 64/112; H10D 64/117

(57) ABSTRACT

Disclosed is a transistor device with an edge termination structure and a method. The method includes forming an edge termination structure of a transistor device. Forming the edge termination structure includes: forming an edge trench in an edge region of a semiconductor body such that the edge trench has a trench bottom and an inner trench sidewall facing an inner region of the semiconductor body; and forming a first edge region of a second doping type adjacent to the inner trench sidewall. Forming the first edge region includes implanting dopant atoms of the second doping type at least into the inner trench sidewall.

### TECHNICAL FIELD

This disclosure relates in general to a transistor device, in particular, a vertical transistor device with an edge termination structure.

### BACKGROUND

A vertical transistor device is a transistor device in which source regions of transistor cells are spaced apart from a drain region of the transistor device in a vertical direction of a semiconductor body. The source regions may be located close to a first surface of the semiconductor body, and the drain region may be located close to a second surface opposite the first surface. Side surfaces (sidewalls) of the semiconductor body are surfaces that terminate the semiconductor body in lateral directions perpendicular to the first and second surfaces.

The transistor cells may be arranged in an inner region of the semiconductor body, wherein the inner region, in lateral directions is surrounded by an edge region. Usually, vertical transistor devices are designed such that the edge region in sections close to the sidewalls is connected to the drain region. In this case, an edge termination structure arranged in the edge region absorbs a voltage that may occur between the drain region and the source regions when the transistor device is in an off-state. The voltage blocking capability is the maximum voltage the transistor device can withstand in the off-state. The edge termination structure may be configured to absorb a voltage that is at least equal to or higher than the voltage blocking capability.

Each of the transistor cells includes a gate electrode that is dielectrically insulated from the semiconductor body by a gate dielectric and is configured to control an operating state of the transistor devices. Usually, a gate controlled transistor device can be operated in a reverse operating mode (diode mode). This is an operating mode in which body diodes formed between body regions of the transistor cells and a drift region are conducting. Operating the transistor device in a diode mode is associated with a charge carrier plasma that is formed in the drift region and includes charge carriers of a first type (e.g. electrons) and a second type (e.g. holes). When the transistor device changes from the diode mode to the off-state the charge carriers forming the charge carrier plasma have to be removed from the drift region in the inner region as well as in the edge region of the semiconductor body.

One example of an edge termination structure is disclosed in US 2020/0105918 A1.

There is a need for an edge termination structure that is capable of withstanding voltages that may occur between the inner region and the edge region of the transistor device and that is capable of efficiently removing charge carriers from the edge region after the transistor device has been operated in the diode mode.

### SUMMARY

One example relates to a transistor device. The transistor device includes a semiconductor body including an inner region and an edge region; a drain region of a first doping type arranged in the inner region and the edge region; a plurality of transistor cells at least partially integrated in the inner region of the transistor device; and an edge termination structure. The edge termination structure includes an edge trench extending from a first surface of the semiconductor body into the edge region, and including a trench bottom and an inner trench sidewall facing the inner region. The edge termination structure further includes a first insulating layer covering the trench bottom and the inner trench sidewall, a first edge region of a second doping type complementary to the first doping type, arranged adjacent to the inner side wall, and connected to a source node of the transistor device, a first field electrode arranged above the first insulating layer, connected to a gate node of the transistor device, and at least partially overlapping the inner trench sidewall in a first lateral direction of the semiconductor body.

Another example relates to a transistor device. The transistor device includes a semiconductor body including an inner region and an edge region; a drain region of a first doping type arranged in the inner region and the edge region; a plurality of transistor cells at least partially integrated in the inner region of the transistor device; and an edge termination structure. The edge termination structure includes an edge trench extending from a first surface of the semiconductor body into the edge region, and including a trench bottom and an inner trench sidewall facing the inner region, a first insulating layer covering the trench bottom and the inner trench sidewall, a first edge region of a second doping type complementary to the first doping type, connected to a source node of the transistor device, and extending from the trench bottom to the first surface of the semiconductor body adjacent to the inner trench sidewall, and a first field electrode arranged above the first insulating layer, connected to a gate node of the transistor device.

Yet another example relates to a method. The method includes forming an edge termination structure of a transistor device. Forming the edge termination structure includes forming an edge trench in an edge region of a semiconductor body such that the edge trench includes a trench bottom and an inner trench sidewall facing an inner region of the semiconductor body, and forming a first edge region of a second doping type adjacent to the inner trench sidewall. Forming the first edge region includes implanting dopant atoms of the second doping type at least into the inner trench sidewall.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a vertical cross-sectional view of one portion of a transistor device that includes a semiconductor body with an inner region and an edge region, transistor cells in the inner region, and an edge termination structure;

FIGS. 2-5 illustrate different modifications of the edge termination structure illustrated in FIG. 1;

FIG. 6 illustrates transistor cells according to one example that each include a gate electrode;

FIG. 7 illustrates one example of the gate electrodes in greater detail;

FIG. 8 illustrates a more detailed vertical cross-sectional view of one portion of a transistor device of the type illustrated in FIG. 1;

FIG. 9 illustrates a modification of the edge termination structure illustrated in FIG. 8;

FIGS. 10A-10B each illustrate a top view of the transistor device according to one example;

FIG. 11 illustrates a vertical cross-sectional view of a transistor device of the type illustrated in FIG. 8 in a vertical section plane different from the vertical section plane illustrated in FIG. 8;

FIG. 12 illustrates an edge termination structure that is based on the edge termination structure according to any one of FIGS. 3-5 and includes additional features;

FIGS. 13-15 and 16A-16D illustrate different examples of methods for forming doped regions of the edge termination structure; and

FIG. 17 illustrates a modification of the method illustrated in FIGS. 16A-16C.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

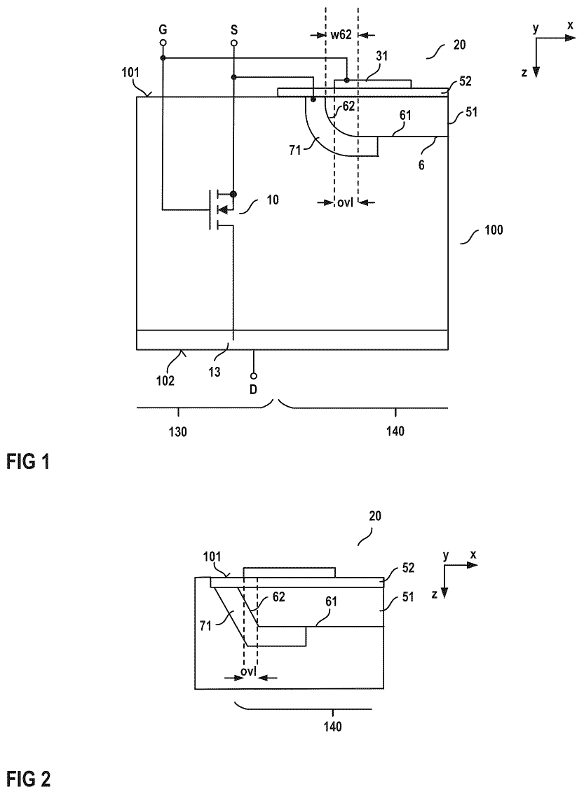

FIG. 1 schematically illustrates a transistor device according to one example. More specifically, FIG. 1 schematically illustrates a vertical cross-sectional view of a portion of the transistor device. The transistor device includes a semiconductor body 100 with a first surface 101 and a second surface 102 opposite the first surface. FIG. 1 illustrates the transistor device in a vertical section plane that is essentially perpendicular to the first and second surfaces 101, 102.

According to one example, the semiconductor body 100 includes a monocrystalline semiconductor material. The semiconductor material is silicon (Si) or silicon carbide (SiC), for example.

Referring to FIG. 1, the semiconductor body 100 includes an inner region 130 and an edge region 140. The edge region 140 surrounds the inner region 130 in lateral directions, which are directions that are essentially parallel to the first and second surfaces 101, 102. In the following, “inner region of the transistor device” denotes those regions of the transistor device that include the inner region 130 of the semiconductor body 100 and sections of the transistor device located adjacent to the first surface 101 in a vertical direction z and located adjacent to the second surface 102 in the vertical direction z. Furthermore, “edge region of the transistor device” denotes those regions of the transistor device that include the edge region 140 of the semiconductor body 100 and sections of the transistor device located adjacent to the first surface 101 and the second surface 102 in the vertical direction z. The vertical direction z is a direction perpendicular to the first and second surfaces 101, 102.

Referring to FIG. 1, the transistor device includes a drain region 13 of a first doping type. The drain region 13 is arranged in the inner region 130 and the edge region 140 of the semiconductor body 100 and may adjoin the second surface 102.

Furthermore, the transistor device includes a plurality of transistor cells 10 that are at least partially integrated in the inner region 130 of the semiconductor body 100. “At least partially integrated” includes that at least portions of the transistor cells are integrated in the semiconductor body and other portions may be arranged on top of the first surface 101. The transistor cells 10 are not illustrated in detail in FIG. 1. Instead, the transistor cells 10 are represented by a circuit symbol of a transistor.

Just for the purpose of illustration, the circuit symbol shown in FIG. 1 represents an N-type transistor device, in particular, an N-type enhancement (normally-off) MOSFET. This, however, is only an example. The transistor device is not restricted to be implemented as an N-type transistor device but can be implemented as a P-type transistor device as well. Furthermore, the transistor device is not restricted to be implemented as a normally-off device but can be implemented as a normally-on device as well.

Referring to FIG. 1, the transistor device further includes an edge termination structure 20. The edge termination structure 20 includes an edge trench 6 extending from the first surface 101 of the semiconductor body 100 into the edge region 140. The edge trench includes a trench bottom 61 and an inner trench sidewall 62, which is a sidewall of the edge trench facing the inner region 130. The edge trench further includes an outer trench sidewall opposite the inner trench sidewall 62. The outer trench sidewall is not illustrated in FIG. 1 and is explained herein further below.

The edge termination structure 20 further includes a first insulating layer 51 that covers the trench bottom 61 and the inner trench sidewall 62. According to one example, the first insulating layer 51 completely fills the edge trench 6.

The edge termination structure 20 further includes a first edge region 71 of a second doping type complementary to the first doping type. The first edge region 71 is arranged adjacent to the inner trench sidewall 62 and is connected to a source node S of the transistor device. According to one example, the first edge region 71 extends along the entire inner trench sidewall 62 from the trench bottom 61 to the first surface 101 of the semiconductor body 100.

Furthermore, the edge termination structure 20 includes a first field electrode 31. The first field electrode 31 is arranged above the first insulating layer 51 and is connected to a gate node G of the transistor device. The first field electrode 31 at least partially overlaps the inner trench sidewall 62 of the edge trench 6. That is, a projection of the first field electrode 31 onto the edge trench 6 in the vertical direction z overlaps the inner trench sidewall 62. In FIG. 1, ov1 denotes the overlap between the first field electrode 31 and the inner trench sidewall 62.

The first field electrode 31 includes doped polysilicon, for example.

At least portions of the inner surface 62 are inclined relative to the vertical direction z, so that the inner trench sidewall 62 has a certain width w62 different from zero in a first lateral direction x. The first lateral direction x is essentially parallel to the first and second surfaces 101, 102. According to one example, the edge trench 6 is elongated in a second lateral direction y perpendicular to the first lateral direction x. The width w62 of the inner trench sidewall 62 in the first lateral direction x is between 0.5 micrometers and 2 micrometers, in particular, between 0.8 micrometers and 1.2, for example.

The source node S is a circuit node of the transistor device to which source regions of the transistor cells 10 are connected. The gate node G of the transistor device is a circuit node to which gate electrodes of the transistor cells 10 are connected to. Examples of the transistor cells that include source regions and gate electrodes are explained herein further below. In addition to the source node S and the gate node G the transistor device further includes a drain node D. The drain node D is a circuit node connected to or formed by the drain region 13.

The first field electrode 31 is a planar electrode, for example. According to one example, the first field electrode 31 is arranged in a horizontal plane that is spaced apart from the first surface 101 of the semiconductor body 100 in the vertical direction z. For this, the first field electrode 31 may be arranged on top of a second insulating layer 52, wherein portions of the second insulating layer 52 are arranged on top of the first insulating layer 51 and other portions may be formed on top of the first surface 101.

The second insulating layer 52 is only schematically illustrated in FIG. 1. The first insulating layer 51 filling the edge trench 6 and the second insulating layer 52 may be formed by the same process, so that the first and second insulating layers 51, 52 may be part of one contiguous insulating layer formed by the same manufacturing process.

Referring to the above, at least portions of the inner trench sidewall 62 are inclined relative to the vertical direction z, so that the edge trench widens towards the first surface 101. Just for the purpose of illustration, the inner trench sidewall 62 illustrated in FIG. 1 is curved, so that there are different inclination angles relative to the vertical direction z at different positions of the inner trench sidewall 62. This, however, is only an example. According to another example illustrated in FIG. 2, the inner trench sidewall 62 is essentially straight. In each of the examples explained hereinabove an edge trench 8 with a curved inner trench sidewall 62 or an essentially straight inner trench sidewall 62 may be used.

Forming the edge trench 6 may include an isotropic etching process using an etch mask formed on top of the first surface 101. In this process, portions of the semiconductor body 100 are removed in directions perpendicular to the first surface 101 and in lateral directions below the etch mask, so that inclined inner and outer trench sidewalls are obtained. This type of method is commonly known, so that no further explanation is required in this regard.

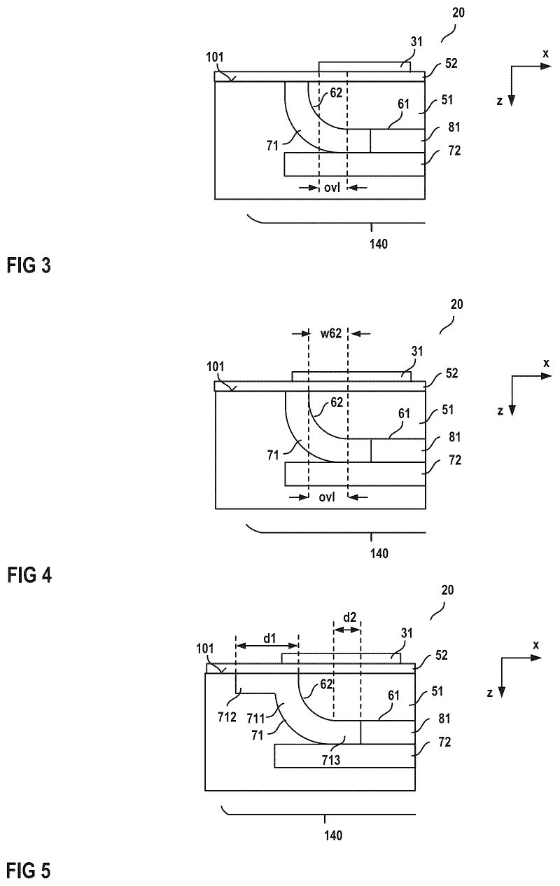

FIGS. 3-5 illustrate various modifications of the edge termination structure 20 illustrated in FIGS. 1 and 2. Just for the purpose of illustration, the inner trench sidewalls 62 are curved in the examples illustrated in FIGS. 3-5.

Referring to FIG. 3, the edge termination structure 20 may further include a second edge region 81 of the first doping type. The second edge region 81 is arranged adjacent to the trench bottom 61 in the vertical direction z and is arranged adjacent to the first edge region 71 in the first lateral direction x. Furthermore, the edge termination structure 20 may include a third edge region 72 of the second doping type. The third edge region 72 is adjacent to the first edge region 71 and the second edge region 82 in the vertical direction z.

Referring to FIG. 4, the first field electrode 31 may entirely overlap the inner trench sidewall 62. In this example, the overlap ov1 equals the width w62 of the inner trench sidewall in the first lateral direction x. In the first lateral direction x, the first field electrode 31 may extend beyond the inner trench sidewall 62 in the direction of the inner region 120. In this example, as illustrated in FIG. 4, the first field electrode 31 overlaps portions of the first edge region 71 that adjoin the inner trench sidewall 62. According to one example (not illustrated) the first field electrode 31 extends beyond the first edge region 71, in the first lateral direction x in the direction of the inner region 130.

Referring to FIG. 5, the first edge region 71 may include three portions (sections), a first portion 711 extending along the inner trench sidewall 62, a second portion 712 extending away from the inner trench sidewall 62 in the first lateral direction x in the direction of the inner region 130 and along the first surface 101, and a third portion 713 extending away from the inner region 130 in the lateral direction x along a portion of the trench bottom 61. A dimension d1 of the second portion 712 in the first lateral direction x is between 1 micrometers and 15 micrometers, in particular, between 3 micrometers and 10 micrometers, for example. A dimension d2 of the third portion 713 in the first lateral direction x is between 1 micrometers and 15 micrometers, in particular, between 2 micrometers and 5 micrometers, for example.

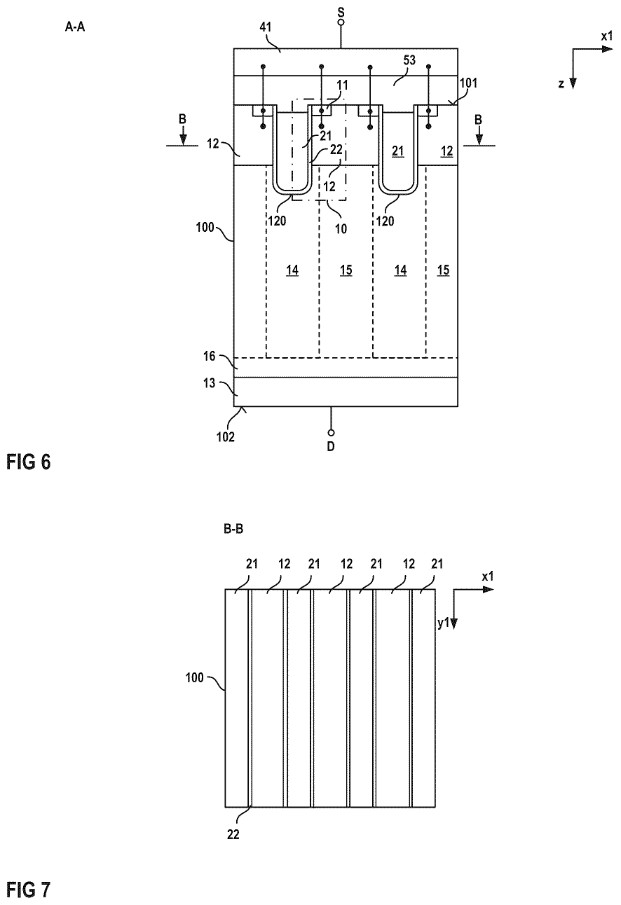

Referring to the above, the transistor device includes a plurality of transistor cells 10 that are at least partially integrated in the inner region 130 of the semiconductor body 100. FIG. 6 schematically illustrates transistor cells 10 according to one example. More specifically, FIG. 6 illustrates a vertical cross-sectional view of one portion of the semiconductor body 100 in which the transistor cells 10 are formed.

Referring to FIG. 6, each transistor cell 10 includes a source region 11 of a first doping type, a body region 12 of a second doping type complementary to the first doping type, and a gate electrode 21. The gate electrode 21 is adjacent to the body region 12, is dielectrically insulated from the body region 12 by a gate dielectric 22, and is arranged in a gate trench 120 extending from the first surface 101 of the semiconductor body 100 into the semiconductor body 100.

Referring to FIG. 6, source and body regions 11, 12 of two neighboring transistor cells 10 may be arranged in a mesa region between neighboring gate trenches 120. In this example, the body regions 12 of the two neighboring transistor cells 10 may be formed by one contiguous doped region of the second doping type. Furthermore, two (other) neighboring transistor cells may share the gate electrode 21. That is, the gate electrodes 21 of two neighboring transistor cells may be formed by one contiguous electrode arranged in one gate trench 120.

The gate electrodes 21 include an electrically conducting material. Examples of the electrically conducting material include doped polysilicon, or a metal such as tungsten (W), titanium (Ti), copper (Cu), aluminum (Al), or the like. The gate dielectric 22 includes an oxide, for example. According to one example, the oxide is silicon oxide (SiO₂).

Referring to the above, the source regions 11 of the transistor cells 10 are connected to the source node S of the transistor device. Referring to FIG. 6, the transistor device may include a source electrode 41, wherein the source electrode 41 either forms the source node S or is connected to the source node S. The source electrode 41 includes an electrically conducting material such as, for example, aluminum (Al), copper (Cu), or an aluminum-copper alloy (AlCu).

The source electrode 41 is electrically connected to the source and body regions 11, 12 of the transistor cells 10. Connections between the source electrode 41 and the source and body regions 11, 12 are only schematically illustrated in FIG. 6. Such connections may be implemented using electrically conducting vias that extend from the source electrode 41 through an insulating layer 53 to the source and body regions 11, 12. This is commonly known, so that no further explanation is required in this regard.

The insulating layer 53 is formed on top of the first surface 101 and the gate electrodes 21 and separates the source electrode 41 from the semiconductor body 100 and the gate electrodes 21. The insulating layer 53 may include portions of the second insulating layer 52 explained herein before.

Referring to FIG. 6, the transistor device further includes a drift region 14 of the first doping type. The drift region 14 adjoins the body regions 12 of the transistor cells 10 so that PN junctions are formed between the body regions 12 and the drift region 14. Furthermore, in the vertical direction, the drift region 14 is arranged between the body regions 12 and the drain region 13.

Optionally, a buffer region 16 of the first doping type and having a doping concentration that is higher than the doping concentration of the drift region 14 and lower than the doping concentration of the drain region 13 is arranged between the drift region 14 and the drain region 13.

Referring to FIG. 6, the gate trenches with the gate electrodes 21 are spaced apart from each other in a third lateral direction x1. The third lateral direction x1 is perpendicular to the vertical direction z of the semiconductor body 100 and may correspond to the first lateral direction x explained above. According to one example, the gate electrodes 21 are implemented as stripe electrodes (elongated electrodes). In this example, the gate electrodes 21, in a fourth lateral direction y1 perpendicular to the third lateral direction x1, are elongated. The fourth lateral direction y1 may correspond to the second lateral direction y explained above.

One example of elongated gate electrodes 21 is illustrated in FIG. 7. FIG. 7 illustrates one portion of the semiconductor body 100 in a first horizontal section plane B-B shown in FIG. 6 that cuts through the gate trenches 120 with the gate electrodes 21 and the gate dielectrics 22. The horizontal sectional plane B-B is essentially parallel to the first and second surfaces 101, 102.

According to one example, the transistor device is implemented as a superjunction transistor device. In this example, the transistor device includes a plurality of compensation regions 15 (illustrated in dashed lines) that are spaced apart from each other in a lateral direction of the semiconductor body 100. Each of the compensation regions 15 is adjacent to a respective portion of the drift region 14.

Just for the purpose of illustration, in the example illustrated in FIG. 6, the compensation regions 15 are spaced apart from each other in the third lateral direction x1. According to another example (not illustrated) the compensation regions 15 are spaced apart from each other in the fourth lateral direction y1.

The transistor device can be operated in an on-state or an off-state. In the on-state, there are conducting channels in the body regions 12 along the gate dielectrics between the source regions 11 and the drift region 14. For this, the drift region 14 adjoins the gate dielectric 22 and the body region 12 of at least one of the transistor cells 10.

Furthermore, each of the optional compensation regions 15 is adjacent to at least one of the portions of the drift region 14 and is connected to the source electrode 41. In the example illustrated in FIG. 6, each of the compensation regions 15 adjoins the body region 12 of at least one transistor cell and is connected to the source electrode 41 via the respective body region 12.

The transistor device can be operated in a conventional way by applying a drive voltage (gate-source voltage) between the gate electrodes 21 and the source electrode 41. The transistor device is in the on-state (conducting state) when the drive voltage is such that conducting channels are generated in the body regions 12 along the gate dielectrics 22 between the source regions 11 and the drift region 14. The transistor device is in the off-state (blocking state) when the electrically conducting channels are interrupted.

The transistor device can be implemented as an N-type transistor device or as a P-type transistor device. An N-type transistor device, for example, is in the on-state, when the drive voltage is higher than a predefined positive threshold voltage and in the off-state, when the drive voltage is below the threshold voltage.

In an N-type transistor device, the doped regions of the first doping type are N-type regions and the doped regions of the second doping type are P-type regions. In a P-type transistor device, the doped regions of the first doping type are P-type regions and the doped regions of the second doping type are N-type regions.

The source regions 11, the body regions 12, the drift and compensation regions 14, 15, the buffer region 16, and the drain region 13 may also be referred to as active device regions. In an N-type transistor device, doping concentrations of the active device regions are selected from the following ranges, for example
Source region 11: 5E19 cm⁻³-5E20 cm⁻³
Body region 12: 3E19 cm³-3E20 cm⁻³
Drain region 13: 5E18 cm⁻³-5E20 cm⁻³
Drift region 14: 7E15 cm⁻³-7E16 cm⁻³
Compensation region 15: 7E15 cm⁻³-7E16 cm⁻³
Buffer region 16: 5E15 cm⁻³-5E16 cm⁻³
Body contact region 17: 1E20 cm⁻³-1E21 cm⁻³

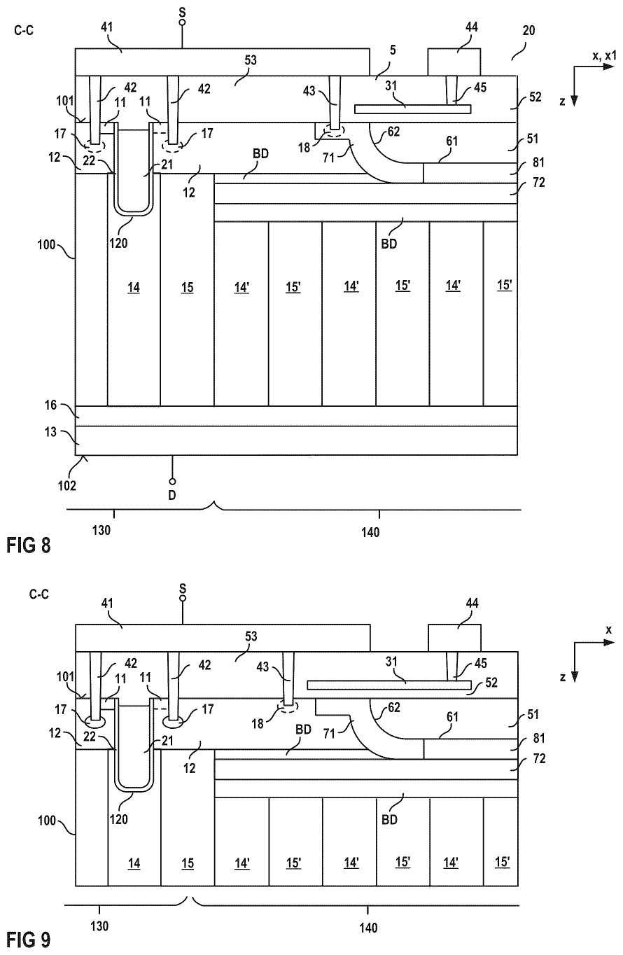

FIG. 8 illustrates one example a transistor device of the type illustrated in FIG. 1 in greater detail. More specifically, FIG. 8 illustrates a vertical cross-sectional view of one portion of the semiconductor body 100, wherein the portion of the semiconductor body 100 illustrated in FIG. 8 includes portions of the inner region 130 and the edge region 140.

The transistor device illustrated in FIG. 8 includes transistor cells of the type illustrated in FIG. 6. Furthermore, the transistor device illustrated in FIG. 8 includes an edge termination structure 20 of the type illustrated in FIG. 5. This, however, is only an example. Any other type of edge termination structure explained herein before may be implemented in the transistor device according to FIG. 8 as well.

The transistor cells illustrated in FIG. 8 are superjunction transistor cells which, in addition to the drift region 14, includes compensation regions 15. According to one example, illustrated in FIG. 8, drift and compensation regions are not only arranged in the inner region 130 but are also arranged in the edge region 140. In the following, the drift regions arranged in the edge region 140 are referred to as edge drift regions 14′, and compensation regions arranged in the edge region 140 are referred to as edge compensation regions 15′. In the vertical direction z, the edge drift and compensation regions 14′, 15′ may be spaced apart farther from the first surface 101 than the drift and compensation regions 14, 15 in the inner region 130.

Referring to the above, the source and body regions 11, 12 of the transistor cells are connected to the source electrode 41. According to one example illustrated in FIG. 8, the source and body regions 11, 12 are connected to the source electrode 41 through electrically conducting vias 42 that extend from the source electrode 41 through the insulating layer 53 into the semiconductor body 100 to the source and body regions 11, 12. Optionally, each transistor cell includes a body contact regions 17 of the second doping type that provides for an ohmic contact between a body region 12 and the respective electrically conducting via 42. The body contact regions 17 have a higher doping concentration than the body regions 12.

Referring to the above, the first edge region 71 is connected to the source node S of the transistor device. For this, in the example illustrated in FIG. 8, the first edge region 71 is connected to the source electrode 41 through at least one electrically conducting via 43. Optionally, a contact region 18 of the second doping type adjoins the via and provides for an ohmic contact between the via 43 and the first edge region 71. The contact region 18 has a higher doping concentration than the first edge region 71.

Referring to FIG. 8, the transistor device further includes a gate runner 44 that is spaced apart from the first field electrode 31 in the vertical direction z and is electrically connected to the first field electrode 31. The gate runner 44 is arranged on top of an insulating layer 5. Portions of the insulating layer 5 separate the gate runner 44 from the first field electrode 31. The insulating layer 5 is arranged between the first surface 101 on one side and the gate runner 44 and the source electrode 41 on the other side. The third insulating layer 53 and the second insulating layer 52 explained herein before are portions of this insulating layer 5.

Referring to the above, the first field electrode 31 is connected to the gate node G. As explained herein further below, the gate runner 44 is connected to the gate node G. Thus, in the example according to FIG. 8, for connecting the first field electrode 31 to the gate node G, the first field electrode 31 is connected to the gate runner 44 through an electrically conducting via 45 extending from the gate runner 44 down to the first field electrode 31 in the insulating layer 5.

Forming the semiconductor body 100 of the transistor device may include epitaxially growing several epitaxial layers one above the other and implanting dopant atoms into each of the epitaxial layers before forming the next one of the epitaxial layers. In particular the drift regions 14, 14′, the compensation regions 15, 15′ and the third edge region 72 may be formed in this way. The source and body regions 11, 12 may be formed by implanting dopant atoms via the first surface 101 into the semiconductor body 100 after having formed each of the epitaxial layers. The drain region 13 may be formed by a semiconductor substrate on top of which the epitaxial layers are grown.

The epitaxial layers have a (low) basic doping, as low as intrinsic, for example. After forming the individual device regions explained before regions may remain in the semiconductor body 100 that include the basic doping of the epitaxial layers. Examples of those regions having the basic doping are illustrated in FIG. 8 and labeled with reference character BD.

Referring to FIG. 8, the plurality of transistor cells include an edge transistor cell, which is that one of the transistor cells that is closest to the edge region 140. The edge transistor cell may include a source region 11 (illustrated in dashed lines in FIG. 8). Alternatively, the source region 11 is omitted in the edge transistor cell.

According to one example, the body region 12 of the edge transistor cell, in a lateral direction extends to the first edge region 71. In the example illustrated in FIG. 8, the third lateral direction x3 in which gate electrodes 21 of the transistor cells 10 are spaced apart from each other corresponds to the first lateral direction x of the edge termination structure 20. In this example, the body region 12 in the first and third lateral directions x, x1 extends to the first edge region 71.

In the example illustrated in FIG. 8, the first field electrode 31 entirely overlaps the inner trenches sidewall 62 and overlaps portions of the first edge region 71. The first field electrode 31, however, does not entirely overlap the first edge region 71, so that the first edge region 71 can be directly connected to the source electrode 41 through the electrically conducting via 43.

FIG. 9 shows a modification of the transistor device according to FIG. 8. In the example illustrated in FIG. 9, the first field electrode 31 entirely overlaps the first edge region 71. In this example, the electrically conducting via 43 connects the source electrode 41 to the body region 12 of the edge transistor cell and, in this way, connects the first edge region 71 adjoining the body region 12 to the source electrode 41.

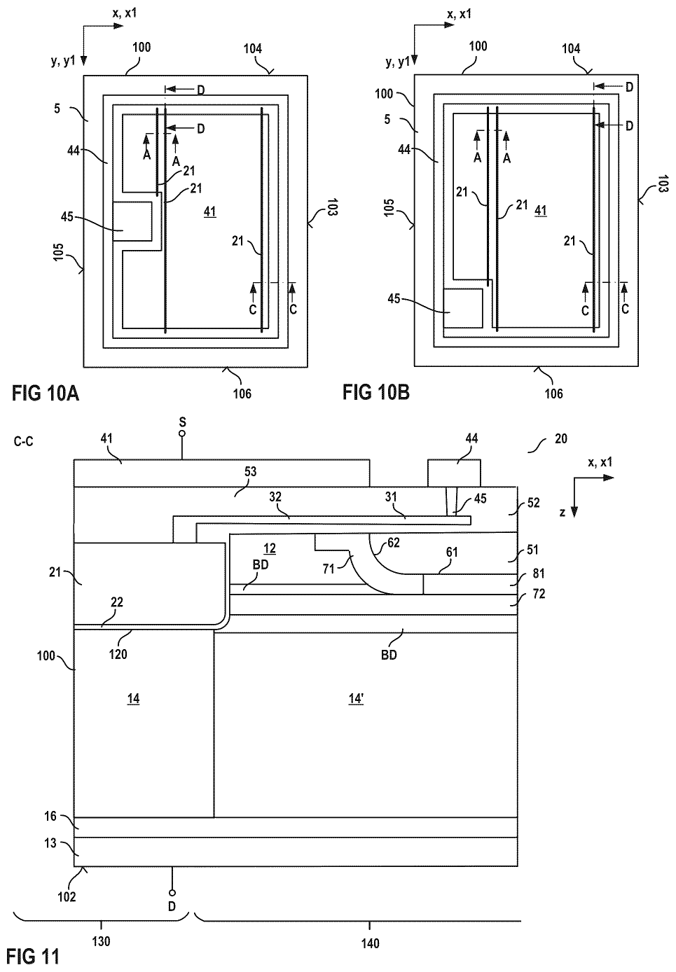

Each of FIGS. 10A and 10B illustrates a top view of a transistor device according to one example. More specifically, each of FIGS. 10A and 10B shows a top view of the semiconductor body 100 with the source electrode 41 and the gate runner 44 formed on top of the insulating layer 5. Referring to FIGS. 10A and 10B, the gate runner 44 surrounds the source electrode 41 in lateral directions of the semiconductor body 100.

The transistor device furthermore includes a gate pad 45 that is connected to the gate runner 44. The gate pad 45 forms the gate node G or is connected to the gate node G of the transistor device. The gate pad 45 may adjoin the gate runner 44, as illustrated in FIGS. 10A and 10B. Alternatively, the gate pad 45 is spaced apart from the gate runner 44 and a resistor (gate resistor) is connected between the gate pad 45 and the gate runner 44.

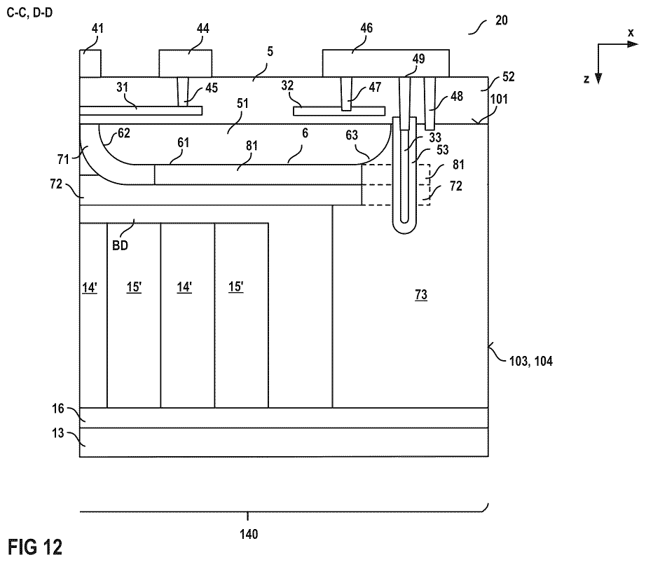

In the example illustrated in FIG. 10A, the gate pad 45 is arranged at a position that is essentially in the middle between two opposing sidewalls 103, 106 of the semiconductor body 100. In the example according to FIG. 12B, the gate pad 45 is arranged at a position that is close to a corner formed by two adjacent sidewalls 105, 106 of the semiconductor body 100.

The transistor cells are out of view in FIGS. 10A and 10B. For the purpose of illustration, the position of three gate electrodes 21 relative to the source electrode 41 and the gate runner 44 are illustrated by bold lines in FIGS. 10A and 10B. In the example illustrated in FIGS. 10A and 10B, the gate electrodes 21 are elongated electrodes, wherein a longitudinal direction of these gate electrodes 21 corresponds to the second and fourth lateral directions y, y1 explained herein before. The vertical cross-sectional view of the transistor cells illustrated in FIG. 6 is a cross-sectional view in section planes A-A illustrated in FIGS. 10A and 10B, for example. The vertical cross-sectional view of the edge transistor cell and an adjoining portion of the edge region illustrated in FIGS. 8 and 9 is a cross-sectional view in section planes C-C illustrated in FIGS. 10A and 10B, for example.

The edge termination structure 20 surrounds the inner region 130 of the semiconductor body 100 in lateral directions. In FIGS. 8 and 9 portions of the edge termination structure 20 are illustrated that are arranged adjacent to the inner region 130 in the first lateral direction x, which equals the third lateral direction x3 in which the gate electrodes 21 of the individual transistor cells are spaced apart from each other and which is perpendicular to a longitudinal directions of the gate electrodes 21. The edge termination structure 20 illustrated in FIGS. 8 and 9 is arranged between the inner region 130 and a first sidewall 103 of the semiconductor body 100 illustrated in FIGS. 10A and 10B. On the opposite side, that is between the inner region 130 and the opposite sidewall 105 the edge termination structure is the same as illustrated in FIGS. 8 and 9.

According to one example, the edge termination structure 20 surrounding the inner region 130 includes that at least the edge trench 6 with the first insulating layer 51, the first edge region 71, and the first field electrode 31 surround the inner region 130 in lateral directions. That is, each of the edge trench 6, the first insulating layer 51, the first edge region 71, and the first field electrode 31 form a closed loop around the inner region 130. According to one example, also the second and third edge regions 81, 71 form a respective closed-loop around the inner region 130.

FIG. 11 shows a vertical cross-sectional view of the edge termination structure 20 arranged between longitudinal ends of the gate trenches 21 and a sidewall of the semiconductor body 100. In addition to the edge termination structure 20, the gate electrode 21 of one transistor cell is illustrated in FIG. 11. The vertical cross-sectional view illustrated in FIG. 11 is a sectional view in section plane D-D illustrated in FIGS. 10A-10B, for example. In this example, the edge termination structure illustrated in FIG. 11 is arranged between the inner region and a second sidewall 104 perpendicular to the first sidewall 103. On the opposite side, that is between the inner region 130 and the opposite sidewall 106 the edge termination structure is the same as illustrated in FIG. 11.

According to one example, each of the gate electrodes 21 is connected to the gate runner 44 at at least one longitudinal end. One example for connecting the gate electrodes 21 illustrated in FIG. 11 to the gate runner 44 is illustrated in FIG. 11. In this example, the gate electrode 21 is connected to the first field electrode 31 via a contact finger 32 extending from the first field electrode 31 to the gate electrodes 21. The first field electrode 31 and the contact finger can be formed by the same process, so that the first field electrode 31 and the contact finger 32 are formed by one contiguous electrode layer. The electrode layer is an electrically conducting layer such as doped polysilicon layer.

Referring to the above, the first edge region 71 is connected to the source electrode 41. In the example illustrated in FIG. 11, the source electrode 41 is connected to the first edge region 71 at positions spaced apart from the contact finger 32, so that no connection between the source electrode 41 and the first edge region 71 is illustrated in FIG. 11.

The figures explained herein before illustrate a portion of the edge termination structure 20 in a section of the edge region 140 adjoining the inner region 130. The remainder of the edge termination structure is not illustrated in these drawings. A vertical cross-sectional view of the entire edge termination structure 20 according to one example is illustrated in FIG. 12. The edge termination structure illustrated in FIG. 12 is based on the edge termination structure according to one of FIGS. 4 and 5. The cross-sectional view illustrated in FIG. 12 is a cross-sectional view in section planes C-C and D-D illustrated in FIGS. 10A and 10B, for example. Thus, FIG. 12 shows a portion of the edge termination structure 20 arranged between the inner region 130 and the first surface 103 or between the inner region 130 and the second surface 104. Between the inner region 130 and the third and fourth surfaces 105, 106 the edge termination structure 20 may be implemented in the same way as illustrated in FIG. 12.

Referring to FIG. 12, the edge trench 6 includes an outer trench sidewall 63, which is a trench sidewall facing the respective sidewall 103, 104 of the semiconductor body 100. According to one example, the edge termination structure 20 further includes a second field electrode 32 that is arranged above the first insulating layer 51. According to one example, the second field electrode 32 at least partially overlaps the outer trench sidewall 63. The other trench sidewall 63 may have the same shape as the inner trench sidewall 62. According to one example, the second field electrode 32 is connected to a drain runner 46. The drain runner 46 is arranged on top of the insulating layer 5 and is spaced apart from both the source electrode 41 and the gate runner 44 in lateral directions. The drain runner 46 includes an electrically conducting material such as, for example, tungsten (W), titanium (Ti), aluminum (Al), copper (Cu), or an alloy of one or more of these materials.

According to one example, the drain runner 46 is connected to the second field electrode 32 through an electrically conducting via 47 extending from the drain runner 46 through portions of the insulating layer 5 to the second field electrode 32.

The drain runner 46 is arranged between the gate runner 44 and the sidewalls 103, 104, 105, 106 of the semiconductor body 100. According to one example, the drain runner 46 forms a closed loop around the source electrode 41, the gate runner 44, and the gate pad 45. In FIGS. 10A and 10B, the drain runner 46, however, is not illustrated.

Referring to FIG. 12, The edge termination structure 20 may further include a field stop 73 of the first doping type. The field stop 73 extends along the sidewalls 103, 104 between the first surface 101 and the buffer region 16 (as illustrated) or the drain regions 13. The field stop region 73 surrounds the inner region 120. That is, the field stop region 73 forms a closed loop around the inner region 130. According to one example, the drain runner 46 is electrically connected to the field stop region 73.

The drain runner 46 may be connected to the field stop region 73 at one or more positions. The drain runner 46 may be connected to the field stop region 73 through an electrically conducting via 46 extending from the drain runner 46 through portions of the insulating layer 5 2 the field stop region 73. According to one example, the drain runner 46 is connected to the field stop region 73 only in regions of the four corners of the semiconductor body 100.

Referring to FIG. 12, the edge termination structure 20 may further include a third field plate 33 that is arranged in a trench extending from the first surface 101 into the field stop region 73. The third field electrode 33 is dielectrically insulated from the semiconductor body 100 by a field electrode dielectric 53. The third field electrode 33 includes an electrically conducting material such as doped polysilicon. The field electrode dielectric 53 includes an oxide, for example. The third field electrode 33 is electrically connected to the drain runner 46 through an electrically conducting via 49, for example.

Referring to FIG. 12, the second and third edge regions 81, 72 may extend beyond the edge trench 6 and the third field electrode 33 in the first lateral direction x in the direction facing away from the inner region 130. This is illustrated in dashed lines in FIG. 12. According to another example (illustrated in solid lines), the second and third edge regions 81, 72, in the first lateral direction x, terminate below the edge trench 6.

The transistor device explained herein before may be operated in a diode mode. This is an operating mode in which a voltage is applied between the drain and source node D, S that forward biases PN junctions between the drift region 14 and the body regions 12 of the transistor cells 10. An N-type transistor device, for example, is in the diode mode when a positive voltage is applied between the drain node D and the source node S and when the transistor cells are driven such that the conducting channels in the body regions 12 along the gate dielectrics 22 are interrupted.

In this operating mode, a charge carrier plasma including charge carriers of the first type (e.g. electrons) and the second type (e.g. holes) is generated in the drift region 14. When the transistor device switches from the diode mode to the off-state, which is an operating mode in which the PN junctions are reverse biased and the conducting channels in the transistor cells 10 are interrupted, the charge carrier plasma has to be removed from the drift regions 14, 14′. The majority charge carriers, which are electrons in an N-type device, are collected by the drain region 13 and the optional buffer region 16 when the transistor device switches from the diode mode to the off-state. The minority charge carriers, which are holes in an N-type transistor device, are collected by the body regions 12 of the transistor cells 10 in the inner region 130 of the transistor device. In the edge region of the transistor device, the first edge region 71 and the optional third edge region 72 efficiently collect the minority charge carriers and, therefore, provide for an increased robustness of the transistor device in the transition between the diode mode and the off-state.

Furthermore, the edge termination structure 20 with the first insulating layer 51 and the optional second and third edge regions 81, 72 efficiently absorb the drain-source voltage in the edge region of the transistor device. The drain source voltage is the voltage applied between the drain node D and the source node S. Due to the field stop region 73 connected to the drain regions 13 the voltage applied between the drain and source node D, S also occurs between the edge surfaces 103-106 and the inner region 130 of the transistor device. The first electrode 31 connected to the gate node G and overlapping the inner trench sidewall 62 shapes the electric field in the edge region in a favorable way so that the edge termination structure 20 is capable of withstanding voltages occurring between the sidewalls and the inner region.

The maximum voltage that may occur between the sidewalls and the inner region 130 is dependent on the voltage blocking capability of the transistor device. The voltage blocking capability device is 600V or higher, for example.

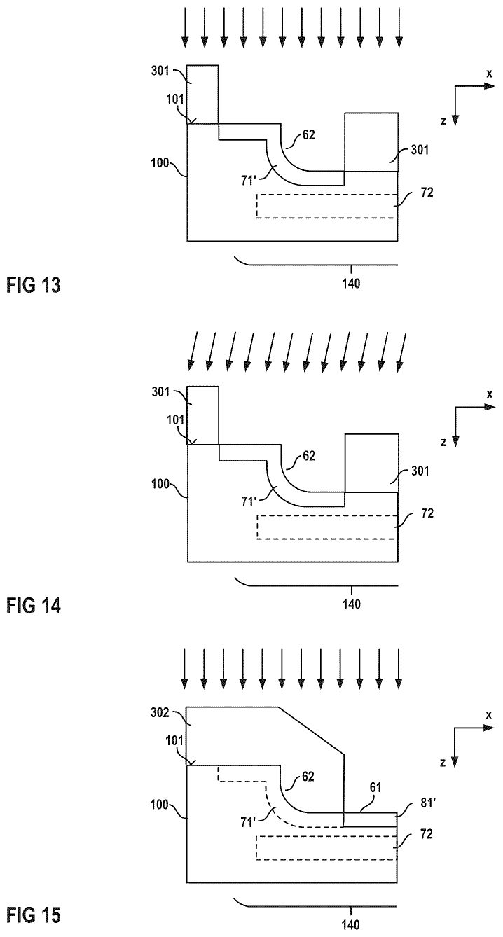

The first, second and third edge regions 71, 81, 72 may be produced in different ways. Examples for forming these edge regions 71, 81, 72 are explained in the following with reference to FIGS. 13, 14, 15 and 16A-16B. Each of these figures shows a portion of the semiconductor body 100 during the respective manufacturing process.

According to one example illustrated in FIG. 13, forming the first edge region 71 includes implanting second type dopant atoms at least into the inner trench sidewall 62 of the edge trench 6. Implanting the second type dopant atoms into the first trench sidewall 62 forms the first section 711 (see, FIG. 5) of the first edge region 71. According to one example, second type dopant atoms are also implanted into sections of the first surface 101 adjoining the trench sidewall 62 and into sections of the trench bottom 61 adjoining the trench sidewall to form second and third sections 712, 713 (see, FIG. 5) of the first edge region 71.

The implantation process uses an implantation mask that has an opening which defines the regions of the semiconductor body 100 into which the dopant atoms are to be implanted. The implantation mask 301 is either a mask formed on top of the semiconductor body 100 (as illustrated) or is a metal mask held spaced apart from the first surface 101 of the semiconductor body.

According to one example illustrated in FIG. 13, a direction in which the second type dopant atoms are implanted essentially equals the vertical direction z. In this case, an implantation angle relative to the vertical direction z is 0.

According to another example illustrated in FIG. 14, the implantation process is a tilted implantation process. The implantation angle relative to the vertical direction z is selected from between 2° and 10°, for example. Furthermore, the implantation angle is such that the implantation direction is inclined towards the inner trench sidewall 62, thereby increasing the implantation dose into the trench sidewall 62 as compared to the example illustrated in FIG. 13.

Referring to the above, the edge trench 6 surrounds the inner region 130 in lateral directions of the semiconductor body 100. In this example the edge trench 6 includes four different inner trench sidewalls, so that the tilted implantation process may include four tilted implantation processes, each for implanting second type dopant atoms into one of the four different inner a trench sidewalls.

The implantation dose is selected from between 1E13 cm⁻² and 5E13 cm⁻², for example. According to one example, the implantation dose is the dose of implanted dopant atoms in an area perpendicular to the implantation direction. The implantation energy is selected from between 120 keV and 180 keV. The dopant atoms are boron atoms, for example.

Implanting the second type dopant atoms results in a first implanted region 71′ in the semiconductor body 100. In addition to implanting the second type dopant atoms, forming the first edge region 71 may include an annealing process in which the implanted second type dopant atoms are activated (and may diffuse in the semiconductor body 100).

The optional third edge region 72 may formed before forming the first edge region 71. According to one example, dopant atoms for forming the third edge region 72 are introduced into the semiconductor body 100 before the implantation process illustrated in FIGS. 13 and 14. In this example, the same annealing process or different annealing processes may be used to activate the implanted atoms forming the first and third edge regions 71, 72.

According to one example illustrated in FIG. 15, forming the second edge region 81 may include implanting first type dopant atoms into the trench bottom 61 using a further implantation must 302. In addition to implanting the first type dopant atoms, forming the second edge region 81 may include an annealing process that activates the implanted first type dopant atoms. The first type dopant atoms for forming the second edge region 81 may be implanted into the semiconductor body before or after implanting the second type dopant atoms for forming the first edge region 71. The same annealing process or different annealing processes may be used to activate the second type dopant atoms implanted for forming the first edge region 71 and the first type dopant atoms implanted for forming the second edge region 81.

Referring to the above, the semiconductor body 100 may include a plurality of epitaxial layers formed one above the other. An uppermost one these epitaxial layers forms the first surface 101 in which the edge trench 6 is formed and into which dopant atoms may be implanted for forming the source and body regions 11, 12 of the transistor cells 10.

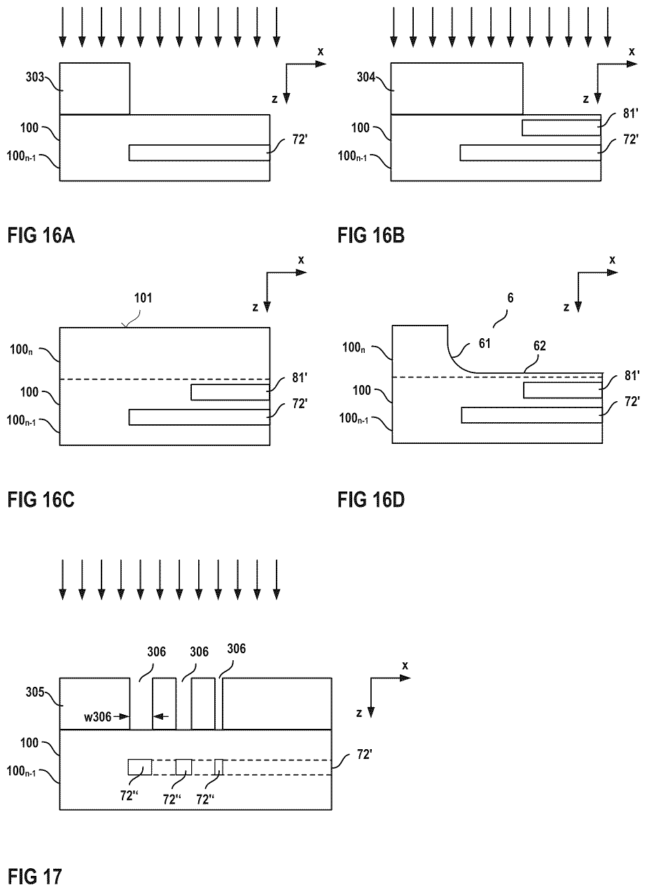

FIG. 16A schematically illustrates a portion of an epitaxial layer 100ₙ₋₁ on top of which the uppermost epitaxial layer is grown. This epitaxial layer 100ₙ₋₁ is referred to as second to last epitaxial layer in the following. According to one example, forming the third edge region 72 includes implanting second type dopant atoms into the second to last epitaxial layer 100ₙ₋₁ using an implantation mask 303 that defines the sections of the epitaxial layer 100ₙ₋₁ into which the dopant atoms are to be implanted. Implanting the second type dopant atoms results in an implanted region 72′ that includes second type dopant atoms. In addition to implanting the second type dopant atoms, forming the third edge region 72 includes an annealing process that activates the implanted dopant atoms.

Referring to the above, forming the second edge region 81 may include implanting dopant atoms into the trench bottom 61. Alternatively, as illustrated in FIGS. 16B, forming the second edge region 81 includes implanting first type dopant atoms into the second to last epitaxial layer using a further implantation mask 304. Implanting the first type dopant atoms results in an implanted region 81′, wherein forming the second edge region 81 includes an annealing process that activates (and diffuses) the implanted first type dopant atoms.

Referring to FIGS. 16C and 16D, the method further includes forming the uppermost epitaxial layer 100ₙ on top of the second to last epitaxial layer 100ₙ₋₁ and forming the edge trench 6 in the semiconductor body 100. According to one example, the edge trench 6 is only formed in the uppermost epitaxial layer 100ₙ. According to another example (not illustrated) the edge trench 6 extends through the uppermost epitaxial layer 100ₙ into portions of the second to last epitaxial layer 100ₙ₋₁.

The annealing process for activating the implanted dopant atoms in the processes illustrated in FIGS. 16A and 16B may be performed after implanting the dopant atoms for forming the first edge region 71.

In the method illustrated in FIGS. 16A-16D, the doping concentration of the third edge region 72 is essentially defined by the implantation dose in the implantation process illustrated in FIG. 16A.

According to one example, the third edge region 72 is formed such that the doping concentration in the third edge region 72 decreases in the first lateral direction x in a direction facing away from the inner region 130. A third edge region 72 of this type may be formed by implanting second type dopant atoms into the second to last epitaxial layer 100ₙ₋₁ in a further implantation process before or after the implantation process illustrated in FIG. 16A. This is illustrated in FIG. 17.

FIG. 17 illustrates a vertical cross-sectional view of the second to last epitaxial layer 100ₙ₋₁ during the further implantation process. The implanted regions 72′ that is formed by the implantation process illustrated in FIG. 6A before the further implantation process is illustrated in dashed lines in FIG. 17.

In the further implantation process illustrated in FIG. 17, second type dopant atoms are implanted into the second to last epitaxial layer 100ₙ₋₁ using an implantation mask 305 that includes several openings 306 that are spaced apart from each other in the lateral direction x. In the further implantation process second type dopant atoms are implanted through the openings 306 into the second to last epitaxial layer 100ₙ₋₁ to from further implanted regions 72″ that locally increase the implantation dose provided by the implantation process illustrated in FIG. 16A.

A width and a mutual distance of the openings 306 in the first lateral direction x defines a gradient of the doping concentration in the finished third edge region 72. According to one example, from opening to opening 306 the width and/or the mutual distance increases in the direction facing away from the inner region 130. According to one example, the further implantation mask 305 is such that in the further implantation process second type dopant atoms are implanted only into those regions that are located below the first edge region 71 in the finished device, in order to provide a gradient of the doping concentration in the third region 72 in regions below the first edge region 71.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device comprising:
a semiconductor body comprising an inner region and an edge region;
a drain region of a first doping type arranged in the inner region and the edge region;
a plurality of transistor cells at least partially integrated in the inner region; and
an edge termination structure,
wherein the edge termination structure comprises:
an edge trench extending from a first surface of the semiconductor body into the edge region, the edge trench having a trench bottom and an inner trench sidewall facing the inner region;
a first insulating layer covering the trench bottom and the inner trench sidewall;
a first edge region of a second doping type complementary to the first doping type, arranged adjacent to the inner sidewall, and connected to a source node of the transistor device; and
a first field electrode arranged above the first insulating layer, connected to a gate node of the transistor device, and at least partially overlapping the inner trench sidewall in a first lateral direction of the semiconductor body.

2. The transistor device of claim 1, wherein the first edge region extends along the inner trench sidewall from the trench bottom to the first surface in the semiconductor body.

3. A transistor device, comprising:
a semiconductor body comprising an inner region and an edge region;
a drain region of a first doping type arranged in the inner region and the edge region;
a plurality of transistor cells at least partially integrated in the inner region; and
an edge termination structure,
wherein the edge termination structure comprises:
an edge trench extending from a first surface of the semiconductor body into the edge region, the edge trench having a trench bottom and an inner trench sidewall facing the inner region;
a first insulating layer covering the trench bottom and the inner trench sidewall;
a first edge region of a second doping type complementary to the first doping type, connected to a source node of the transistor device, and extending from the trench bottom to the first surface of the semiconductor body adjacent to the inner trench sidewall; and
a first field electrode arranged above the first insulating layer and connected to a gate node of the transistor device.

4. The transistor device of claim 3, wherein the first field electrode at least partially overlaps the inner trench sidewall in a first lateral direction of the semiconductor body.

5. The transistor device of claim 4, wherein the first edge region extends, in the first lateral direction, along the first surface for a first distance.

6. The transistor device of claim 5, wherein the first distance is between 1 micrometer and 15 micrometers.

7. The transistor device of claim 4, wherein the first field electrode completely overlaps the inner trench sidewall in the first lateral direction.

8. The transistor device of claim 7, wherein the first field electrode extends beyond the inner trench sidewall in the first lateral direction.

9. The transistor device of claim 4, wherein the first edge region extends, in the first lateral direction, along the trench bottom for a second distance.

10. The transistor device of claim 9, wherein the second distance is between 1 micrometer and 15 micrometers.

11. The transistor device of claim 4, wherein the edge termination structure further comprises a second edge region of the first doping type, and wherein the second edge region is arranged adjacent to the trench bottom in a vertical direction of the semiconductor body and is arranged adjacent to the first edge region in the first lateral direction.

12. The transistor device of claim 11, wherein the edge termination structure further comprises a third edge region of the second doping type, and wherein the third edge region is adjacent to the first edge region in the vertical direction.

13. The transistor device of claim 3, further comprising:
a gate runner connected to the first field electrode, and spaced apart from the first surface in a vertical direction of the semiconductor body.

14. The transistor device of claim 3, wherein the edge termination structure further comprises:
a field stop region of the first doping type adjoining sidewalls of the semiconductor body; and
a second field electrode arranged above the first insulating layer and connected to the field stop region.

15. The transistor device of claim 14, further comprising:
a drain runner connected to the second field electrode and the field stop region, and spaced apart from the first surface in a vertical direction of the semiconductor body.

16. The transistor device of claim 15, wherein the edge termination structure further comprises:
a third field electrode arranged in a field electrode trench extending from the first surface into the semiconductor body,
wherein the third field electrode is dielectrically insulated from the semiconductor body by a field electrode dielectric, and is connected to the drain runner.

17. The transistor device of claim 13, wherein each of the transistor cells comprises a gate electrode connected to the gate runner.

18. The transistor device of claim 17, further comprising:
a source electrode, and
wherein each of the transistor cells comprises a source region connected to the source electrode.

19. The transistor device of claim 18, wherein the gate runner and the source electrode are arranged above the first surface of the semiconductor body.

20. The transistor device of claim 3, wherein the drain region is arranged adjacent to a second surface opposite the first surface of the semiconductor body.

21. The transistor device of claim 3, further comprising:
a plurality of drift regions of the first doping type in the inner region and the edge region; and
a plurality of compensation regions of the second doping type in the inner region and the edge region.

22. The transistor device of claim 3, wherein the semiconductor body further comprises sidewalls, and wherein the edge region is arranged between the inner region and the sidewalls.

23. The transistor device of claim 3, wherein at least portions of the inner trench sidewall are inclined relative to a vertical direction of the semiconductor body.

24. A method, comprising:
forming an edge termination structure of a transistor device,
wherein forming the edge termination structure comprises:
forming an edge trench in an edge region of a semiconductor body such that the edge trench has a trench bottom and an inner trench sidewall facing an inner region of the semiconductor body; and
forming a first edge region of a second doping type adjacent to the inner trench sidewall,
wherein forming the first edge region comprises implanting dopant atoms of the second doping type at least into the inner trench sidewall.

25. The method of claim 24, further comprising:
forming a first insulating layer covering the inner trench sidewall and the trench bottom; and
forming a first field electrode arranged above the first insulating layer and at least partially overlapping the inner trench sidewall in a first lateral direction of the semiconductor body.

26. The method of claim 24, wherein implanting the dopant atoms of the second doping type comprises a tilted implantation process.

27. The method of claim 26, wherein a tilt angle of the implantation process relative to a vertical direction of the semiconductor body is between 1° and 10°.

28. The method of claim 27, wherein an implantation dose of the implantation process is selected from between 1E13 cm⁻² and 5E13 cm⁻².

29. The method of claim 27, wherein an implantation energy of the implantation process is selected from between 100 keV and 200 keV.

30. The method of claim 24, further comprising:
forming a second edge region of a first doping type complementary to the second doping type such that the second edge region is arranged adjacent to the trench bottom in a vertical direction of the semiconductor body and is arranged adjacent to the first edge region in a first lateral direction.

31. The method of claim 30, wherein forming the second edge region comprises implanting dopant atoms of the first doping type into the trench bottom.

32. The method of claim 30, wherein forming the second edge region comprises implanting dopant atoms into a first semiconductor layer, wherein a second semiconductor layer is formed on top of the first semiconductor layer, and wherein the edge trench is formed in the second semiconductor layer.

33. The method of claim 32, further comprising:
forming a third edge region of the second doping type such that the third edge region is adjacent to the first edge region in the vertical direction of the semiconductor body,
wherein forming the third edge region comprises implanting dopant atoms of the second doping type into the first semiconductor layer.
